(19) United States
(12) Patent Application Publication
(10) Pub. No.: US 2023/0317879 A1
(43) Pub. Date: Oct. 5, 2023

(54) ULTRAVIOLET LIGHT-EMITTING DEVICE

(71) Applicant: Xiamen San'an Optoelectronics Co., Ltd., Fujian (CN)

(72) Inventors: Mingchun TSENG, Fujian (CN); Kangwei PENG, Fujian (CN); Suhui LIN, Fujian (CN); Bin JIANG, Fujian (CN); Chungying CHANG, Fujian (CN)

(73) Assignee: Xiamen San'an Optoelectronics Co., Ltd., Fujian (CN)

(21) Appl. No.: 18/089,500

(22) Filed: Dec. 27, 2022

(30) Foreign Application Priority Data
Apr. 2, 2022 (CN) 202210351829.0

(51) Int. Cl. H01L 33/38; H01L 27/15; H01L 33/24; H01L 33/32; H01L 33/46; H01L 33/62

(52) U.S. Cl. CPC H01L 33/38; H01L 27/153; H01L 33/24; H01L 33/32; H01L 33/46; H01L 33/62; H01L 2933/0016; H01L 2933/0025

(57) ABSTRACT

The disclosure provides a ultraviolet light-emitting device, which includes a substrate and multiple light-emitting structures. The light-emitting structures are disposed on the substrate and electrically connected to each other. Each light-emitting structure includes a first semiconductor layer, a light-emitting layer, a second semiconductor layer, a first contact electrode, and a second contact electrode. The first semiconductor layer is located between the substrate and the light-emitting layer. The light-emitting layer is located between the first semiconductor layer and the second semiconductor layer. The first contact electrode is located on the first semiconductor layer, and the second contact electrode is located on the second semiconductor layer. Viewing from the top, the second contact electrode of each light-emitting structure has four edges, and the four edges are sequentially defined as the first edge, the second edge, the third edge, and the fourth edge in an annular direction.

### CROSS-REFERENCE TO RELATED APPLICATION

This application claims the priority benefit of China application serial no. 202210351829.0, filed on Apr. 2, 2022. The entirety of the above-mentioned patent application is hereby incorporated by reference herein and made a part of this specification.

### BACKGROUND

### Technical Field

The disclosure relates to a semiconductor optoelectronic device, and more particularly to a light-emitting device, in particular, to an ultraviolet light-emitting device.

### Description of Related Art

Ultraviolet light-emitting diode (LED) is a solid-state semiconductor device that can directly convert electrical energy into ultraviolet light. The current UV LED products are typically designed as a single chip. Depending on the requirement of current industry, the main sizes adopted include 40×40 mil, 30×30 mil, 20×20 mil, 10×20 mil, etc. The optical power of the ultraviolet light-emitting diode and the driving current are normally in a linear relationship, that is to say, as the driving current increases, the optical power of the light output by the ultraviolet light-emitting diode increases. However, the problem that follows is serious light decay phenomenon, and light decay phenomenon will reduce the output of optical power and reduce the sterilization effect. In addition, conventional ultraviolet light-emitting diode has a high void rate on an electrode surface, the reliability of the package structure obtained after packaging is low, and the performance cannot be ensured. Therefore, how to improve the luminous property of ultraviolet light-emitting diodes, delay the light decay characteristics and reduce the void rate of the surface has become one of the technical problems to be solved urgently in the art.

### SUMMARY

The disclosure provides an ultraviolet light-emitting device, which includes a substrate and a plurality of light-emitting structures.

A plurality of light-emitting structures are disposed on the substrate, and the plurality of light-emitting structures are electrically connected to each other. Each light-emitting structure includes a first semiconductor layer, a light-emitting layer, a second semiconductor layer, a first contact electrode, and a second contact electrode. The light-emitting layer is located between the first semiconductor layer and the second semiconductor layer, the first contact electrode is located on the first semiconductor layer, and the second contact electrode is located on the second semiconductor layer.

Preferably, viewing from the top of the ultraviolet light-emitting device toward the substrate, the second contact electrode of each light-emitting structure has four edges, and the four edges are sequentially defined as the first edge, the second edge, the third edge, and the fourth edge in an annular direction. The first contact electrode at least encloses three edges of the four edges.

The present disclosure further provides a light-emitting device, which adopts the ultraviolet light-emitting device described in any of the above embodiments.

An advantage of the present disclosure is to provide an ultraviolet light-emitting device, which adopt a small current to drive multiple small chips (multiple light-emitting structures) instead of driving with large current adopted for a single large chip, thereby overcoming the light decay characteristics caused by driving with large current in conventional ultraviolet light-emitting diodes, and improving the electro-optical conversion efficiency of ultraviolet light-emitting devices, enhance the luminous property of ultraviolet light-emitting devices, and reinforcing sterilization and disinfection capabilities. Further, the configuration of at least enclosing three edges of the four edges of the second contact electrode by the first contact electrode may effectively reduce a void rate on a surface of the pad, ensure that the package structure formed by packaging the ultraviolet light-emitting device has high reliability, and ensure the service performance of the package structure.

Other features and advantages of the present disclosure will be set forth in the description which follows, and in part will be apparent from the description, or may be learned by practice of the disclosure. The objectives and other advantageous effects of the present disclosure may be realized and attained by the structure specifically pointed out in the description, claims and the like.

### BRIEF DESCRIPTION OF THE DRAWINGS

FIG. 1 is a schematic top view of a structure of an ultraviolet light-emitting device according to an embodiment of the present disclosure.

FIG. 2 is a schematic view showing the dimension of FIG. 1.

FIG. 3 is a schematic longitudinal cross-sectional view taken along the section line A-A of FIG. 1.

FIG. 4A is a schematic top view showing the morphology of a conventional ultraviolet light-emitting diode.

FIG. 4B is a schematic view of surface voids of the ultraviolet light-emitting diode of FIG. 4A.

FIG. 5A is a schematic top view showing the morphology of an ultraviolet light-emitting device according to an embodiment of the present disclosure.

FIG. 5B is a schematic view of surface voids of the ultraviolet light-emitting device of FIG. 5A.

FIG. 6 is a schematic view of a comparison of external quantum efficiency between the ultraviolet light-emitting device of the present disclosure and conventional ultraviolet light-emitting diode.

FIG. 7 to FIG. 13 are schematic top views showing structures of the ultraviolet light-emitting device shown in FIG. 1 in various stages of a manufacturing process of the present disclosure.

FIG. 14 is a schematic top view showing a structure of an ultraviolet light-emitting device according to another embodiment of the present disclosure.

FIG. 15 is a schematic top view showing a structure of an ultraviolet light-emitting device according to still another embodiment of the present disclosure.

FIG. 16 is a schematic top view showing a structure of an ultraviolet light-emitting device according to yet another embodiment of the present disclosure.

FIG. 17 is a schematic top view showing a structure of an ultraviolet light-emitting device according to still another embodiment of the present disclosure.

FIG. 18 is a schematic top view showing a structure of an ultraviolet light-emitting device according to yet another embodiment of the present disclosure.

FIG. 19 is a schematic top view showing a structure of an ultraviolet light-emitting device according to still another embodiment of the present disclosure.

FIG. 20 is a schematic top view showing a structure of an ultraviolet light-emitting device according to yet another embodiment of the present disclosure.

FIG. 21 is a schematic top view showing a structure of an ultraviolet light-emitting device according to still another embodiment of the present disclosure.

FIG. 22 is a schematic view showing a structure of an ultraviolet light-emitting device according to another embodiment of the present disclosure.

### DESCRIPTION OF THE EMBODIMENTS

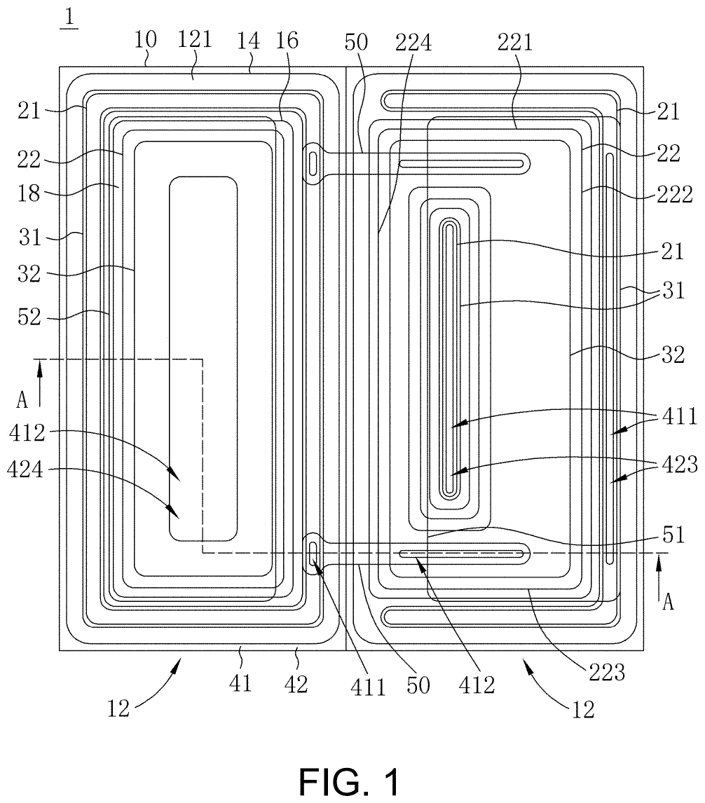

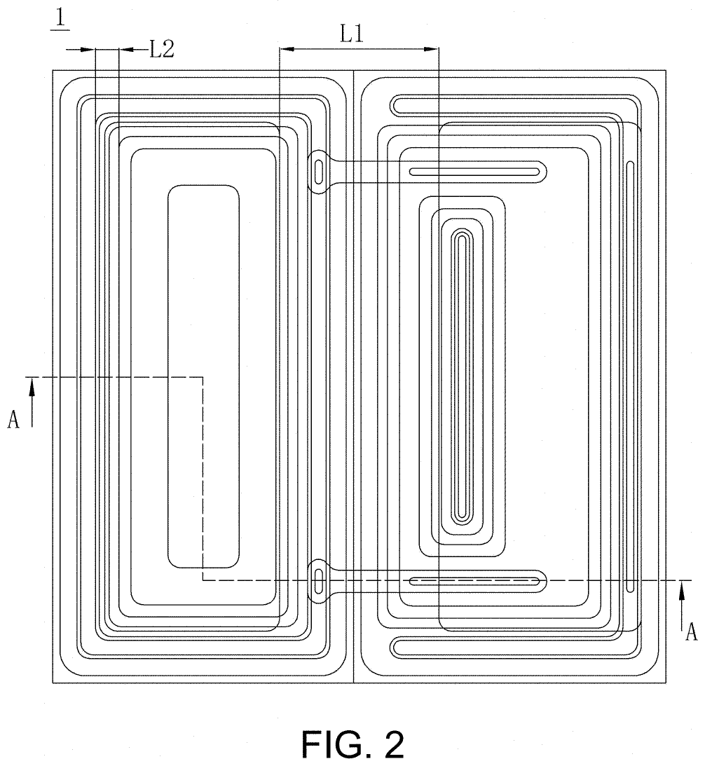

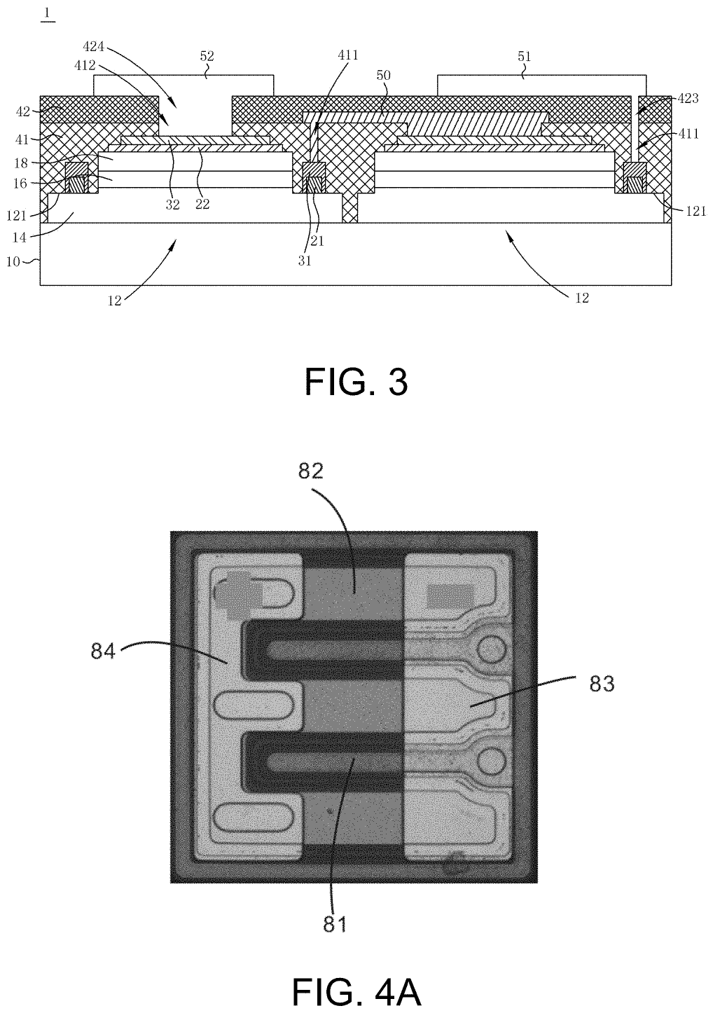

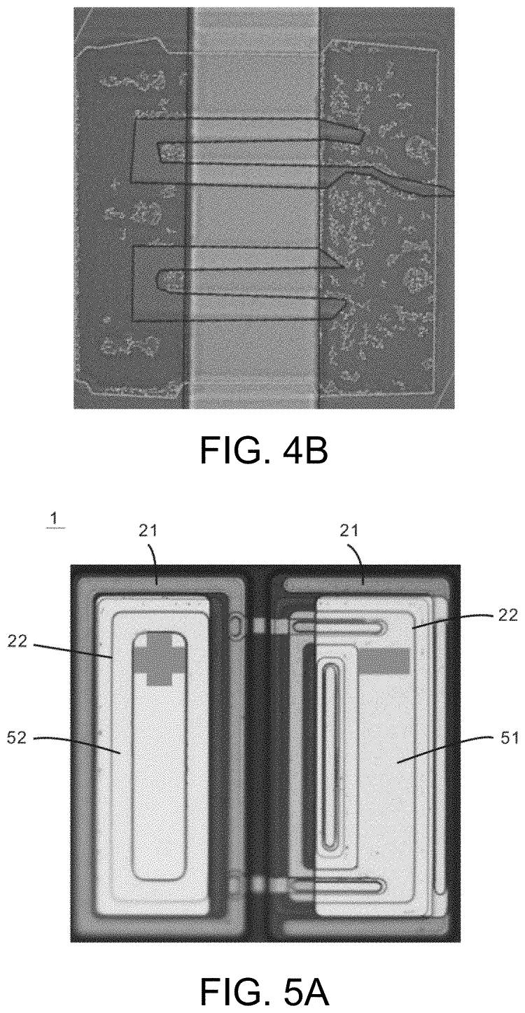

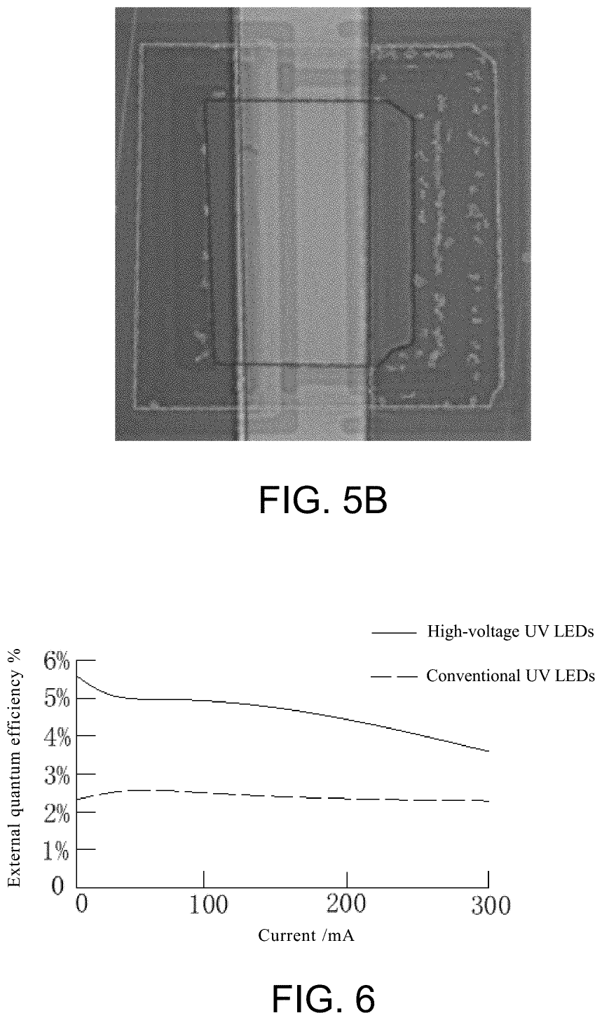

Please refer to FIG. 1 to FIG. 6. FIG. 1 is a schematic top view of a structure of an ultraviolet light-emitting device 1 according to an embodiment of the present disclosure; FIG. 2 is a schematic view showing the dimension of FIG. 1; FIG. 3 is a schematic longitudinal cross-sectional view taken along the section line A-A of FIG. 1; FIG. 4A is a schematic top view showing the morphology of a conventional ultraviolet light-emitting diode; FIG. 4B is a schematic view of surface voids of the ultraviolet light-emitting diode of FIG. 4A; FIG. 5A is a schematic top view showing the morphology of an ultraviolet light-emitting device according to an embodiment of the present disclosure; FIG. 5B is a schematic view of surface voids of the ultraviolet light-emitting device of FIG. 5A; FIG. 6 is a schematic view of a comparison of external quantum efficiency between the ultraviolet light-emitting device of the present disclosure and the ultraviolet light-emitting diode shown in FIG. 4. To achieve at least one of the above advantages or other advantages, an embodiment of the present disclosure provides an ultraviolet light-emitting device 1. As shown in the figures, the ultraviolet light-emitting device 1 may at least include a substrate and a plurality of light-emitting structures 12.

The plurality of light-emitting structures 12 are disposed on the substrate 10. The substrate 10 may be an insulating substrate, preferably, the substrate 10 may be made of a transparent material or a semi-transparent material. In the illustrated embodiment, the substrate is a sapphire substrate. In some embodiments, the substrate 10 may be a patterned sapphire substrate, but the disclosure is not limited thereto. The substrate 10 may also be made of a conductive material or a semiconductor material. For example, the material of the substrate 10 may include at least one of silicon carbide (SiC), silicon (Si), magnesium oxide (MgO) and gallium nitride (GaN). In order to enhance the light extraction efficiency of the substrate 10, especially the effect of light extraction from a surface of the substrate 10, the thickness of the substrate 10 may be increased as required, and the thickness may be increased to 200 μm to 900 μm, such as 250 μm to 400 μm, or 400 μm to 550 μm, or 550 μm to 750 μm.

The plurality of light-emitting structures 12 are electrically connected to each other, for example, the plurality of light-emitting structures 12 may be connected in series, in parallel, or in a serial-parallel connection. In this embodiment, the plurality of light-emitting structures 12 are connected in series.

Each light-emitting structure 12 may at least include a first semiconductor layer 14, a light-emitting layer 16, a second semiconductor layer 18, a first contact electrode 21, and a second contact electrode 22.

The first semiconductor layer 14 is located between the substrate 10 and the light-emitting layer 16, and the light-emitting layer 16 is located between the first semiconductor layer 14 and the second semiconductor layer 18. In other words, the substrate 10, the first semiconductor layer 14, the light-emitting layer 16, and the second semiconductor layer 18 are arranged in sequence along the direction from the substrate 10 to the light-emitting structure 12. The first semiconductor layer 14, the light-emitting layer 16, and the second semiconductor layer 18 may form an epitaxy structure, and the epitaxy structure may provide a light with a specific central emission wavelength, such as ultraviolet light, deep ultraviolet light, and the like. Optionally, an aluminum nitride underlayer (not shown in the figure) may further be provided between the upper surface of the substrate 10 and the first semiconductor layer 14, the aluminum nitride underlayer is in contact with the upper surface of the substrate 10, and the thickness of the aluminum nitride underlayer is preferably is 1 μm or less. Further, the aluminum nitride underlayer includes a low-temperature layer, an intermediate layer and a high-temperature layer in sequence from one side close to the substrate 10, which contributes to the growth of an epitaxy structure with excellent crystallinity. In some other preferred embodiments, a series of hole structures may also be formed in the aluminum nitride underlayer, which helps to release the stress in the epitaxy structure. The series of holes is preferably a series of elongated holes extending along the thickness of the aluminum nitride underlayer, and the depth of holes may be, for example, 0.5 μm to 1.5 μm.

The first semiconductor layer 14 may be an N-type semiconductor layer, and may provide electrons to the light-emitting layer 16 under the action of a power supply. In some embodiments, the first semiconductor layer 14 includes an N-type doped nitride layer. The N-type doped nitride layer may include one or more N-type impurities of group IV elements. In some embodiments, a buffer layer may further be disposed between the first semiconductor layer 14 and the substrate 10 to alleviate lattice mismatch between the substrate 10 and the first semiconductor layer 14. The buffer layer may include an unintentionally doped GaN layer (un-doped GaN, referred to as: u-GaN), or an unintentionally doped AlGaN layer (un-doped AlGaN, referred to as: u-AlGaN), or an unintentionally doped AlN layer (un-doped AlN, referred to as: u-AlN). The light-emitting layer 16 may be a quantum well structure (QW for short). In some embodiments, the light-emitting layer 16 may also be a multiple quantum well structure (MQW for short). The multiple quantum well structure includes a plurality of quantum well layers and a plurality of quantum barrier layers arranged alternately in a repeated manner and may be, for example, a multiple quantum well structure of GaN/AlGaN, InAlGaN/InAlGaN or InGaN/AlGaN. In addition, the composition and thickness of the well layer in the light-emitting layer 16 determine the wavelength of the generated light. In order to improve the luminous efficiency of the light-emitting layer 16, the object may be achieved by changing the depth of the quantum wells, the number of layers, thicknesses and/or other characteristics of the paired quantum wells and quantum barriers in the light-emitting layer 16. In the embodiment, the light-emitting wavelength range of the ultraviolet light-emitting device 1 is 190 nm to 420 nm, that is, the light-emitting wavelength range of the light-emitting layer 16 is 190 nm to 420 nm.

The second semiconductor layer 18 may be a P-type semiconductor layer, which may provide cavities to the light-emitting layer 16 under the action of a power supply. In some embodiments, the second semiconductor layer 18 includes a P-type doped nitride layer. The P-type doped nitride layer may include one or more P-type impurities of group II elements. The P-type impurities may include one or a combination of Mg, Zn, and Be. The second semiconductor layer 18 may be a single-layer structure or a multi-layer structure having different compositions. In addition, the arrangement of the epitaxy structure is not limited thereto, and other types of epitaxy structures may be selected according to actual requirements.

In a specific embodiment, the first semiconductor layer 14 is an n-AlGaN layer, the light-emitting layer 16 is a multiple quantum well structure that emits ultraviolet rays. The multi quantum well structure includes a well layer and a barrier layer, and the number of repetition of the well layer and the barrier layer may be between 1 and 10. The well layer may be an AlGaN layer, and the barrier layer may be an AlGaN layer, but the Al composition of the well layer is lower than that of the barrier layer. The second semiconductor layer 18 may be a p-AlGaN layer or a p-GaN layer, or a stacked structure in which a p-AlGaN layer and a p-GaN layer are stacked. In some embodiments, the second semiconductor layer 18 includes a p-GaN contact layer, the p-GaN contact layer is connected to the second contact electrode 22 to form a good ohmic contact, and the p-GaN contact layer is an upper surface layer of the second semiconductor layer 18. The thickness of the p-GaN contact layer is 5 nm to 50 nm. By setting the thin-film p-GaN contact layer, it is possible to achieve both the internal quantum luminous efficiency and the external quantum luminous efficiency of the ultraviolet light-emitting device 1. Specifically, the p-GaN contact layer having the thickness in the specified range facilitates lateral spreading of the p-side current without causing excessive light absorption.

The first contact electrode 21 is located on the first semiconductor layer 14 and forms a good ohmic contact with the first semiconductor layer 14. The first contact electrode 21 may be a single-layer, a double-layer or a multi-layer structure, such as: Ti/Al, Ti/Al/Ti/Au, Ti/Al/Ni/Au, V/Al/Pt/Au and other stacked structures.

The second contact electrode 22 is located on the second semiconductor layer 18 and forms an ohmic contact with the second semiconductor layer 18. The second contact electrode 22 may be made of a transparent conductive material or a metal material, which may be adaptively selected according to the doping of the surface layer (e.g., the p-GaN contact layer) of the second semiconductor layer 18. In some embodiments, the second contact electrode 22 is made of a transparent conductive material, and the material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO) or zinc oxide (ZnO), but the embodiments of the present disclosure are not limited thereto.

When viewed from the top of the ultraviolet light-emitting device 1 toward the substrate 10, that is, as shown in FIG. 1 and FIG. 2, the second contact electrode 22 of each light-emitting structure 12 has four edges, and the four edges are defined as a first edge 221, a second edge 222, a third edge 223 and a fourth edge 224 in sequence in an annular direction. In this embodiment, the annular direction is clockwise. In each light-emitting structure 12, the first contact electrode 21 at least encloses three edges of the four edges of the second contact electrode 22. This arrangement may effectively reduce the void rate of the surface of the first pad 51 and the second pad 52 to be subsequently arranged, ensure that the package structure formed by packaging the ultraviolet light-emitting device 1 has high reliability, and ensure the usability of the package structure.

Specifically, as shown in FIG. 4A, FIG. 4B, FIG. 5A and FIG. 5B, the dense points in FIG. 4B and FIG. 5B are voids. In a conventional ultraviolet light-emitting diode, the P electrode 82 is in an “E” shape, and the N electrode 81 is embedded in the blank part of the “E”-shaped P electrode. The P pad 84 is formed on the P electrode 82 and avoids the N electrode 81, so there are not many voids. The N pad 83 is formed on the N electrode 81 and the P electrode 82, because there is a height difference inherently existing between the N electrode 81 and the P electrode 82 (the height difference formed by epitaxy hole), which causes the N pad 83 to have an uneven surface when spanning the N electrode 81 and the P electrode 82, and a large number of voids appear; the overall void rate is about 13.53%. When the conventional ultraviolet light-emitting diode is packaged into a package structure, and the package structure is subjected to a thrust test, it is found that the reliability of such package structure is low, and the performance thereof cannot be ensured. In contrast, in the ultraviolet light-emitting device 1 of this embodiment, although there is still a height difference between the first contact electrode 21 and the second contact electrode 22, since the first contact electrode 21 at least encloses three edges of the second contact electrode 22, that is, the position of the height difference is transferred to the edge of the light-emitting structure 12, so that the first pad 51 will not dramatically span the first contact electrode 21 and the second contact electrode 22 when the configuration is set. In this manner, the void rate of the surface of the first pad 51 is reduced, and the overall void rate is about 6.25%. After the ultraviolet light-emitting device 1 is packaged to form a package structure, and the package structure is subjected to a thrust test, it is found that the reliability of such package structure is significantly improved, the anti-forward thrust thereof is increased from 471 grams to 563 grams, and the anti-reverse thrust thereof is increased from 529 grams to 604 grams.

In an embodiment, as shown in FIG. 1 to FIG. 3, each light-emitting structure 12 has a mesa 121. The mesa 121 is configured to expose the first semiconductor layer 14, so that the first contact electrode 21 may be disposed on the mesa 121, thereby ensuring that the first contact electrode 21 is electrically connected to the first semiconductor layer 14. That is, the mesa 121 refers to the upper surface of the first semiconductor layer 14 that is not shielded by the light-emitting layer 16. The horizontal projection area of the mesa 121 of each light-emitting structure 12 accounts for 30%˜70% of the horizontal projection area of each light-emitting structure 12. In this manner, not only the effective area of the light-emitting layer 16 may be ensured, but also the light output of the light-emitting layer 16 may be ensured. The overall operating voltage may also be reduced, and the area of the mesa 121 of the first semiconductor layer 14 may also be ensured. Accordingly, the subsequent elements (such as the first contact electrode 21, the first protection electrode 31, etc.) have sufficient setting area, and the internal elements may be enclosed, for example, the first contact electrode 21 encloses the second contact electrode 22.

Considering that in the field of ultraviolet light-emitting diodes, current injection from N-side is more difficult, therefore, the horizontal projection area of the first contact electrode 21 of each light-emitting structure 12 accounts for 10% to 40% of the horizontal projection area of each light-emitting structure 12, so as to ensure the current injection performance of the first contact electrode 21 and realize the reliability of the first contact electrode 21.

The horizontal projection area refers to the projection area of each element (such as the mesa 121, the first contact electrode 21, etc.) projected onto the horizontal plane in the case where the ultraviolet light-emitting device 1 is placed on a horizontal plane in an upright manner, and the direction from the first semiconductor layer 14 to the substrate 10 is a vertical direction perpendicular to the horizontal plane.

In an embodiment, as shown in FIG. 1 to FIG. 3, each light-emitting structure 12 may further include a first protection electrode 31 and a second protection electrode 32. The ultraviolet light-emitting device 1 may further include a first insulating structure 41, a bridge electrode 50, a second insulating structure 42, a first pad 51, and a second pad 52.

The first protection electrode 31 covers the first contact electrode 21 for protecting the first contact electrode 21. The second protection electrode 32 covers the second contact electrode 22 for protecting the second contact electrode 22. The first protection electrode 31 and the second protection electrode 32 may protect the first contact electrode 21 and the second contact electrode 22 to prevent the first contact electrode 21 and the second contact electrode 22 from being damaged in subsequent manufacturing processes. Preferably, the first protection electrode 31 completely covers the first contact electrode 21, and the second protection electrode 32 completely covers the second contact electrode 22, so as to better protect the first contact electrode 21 and the second contact electrode 22, thus preventing the first contact electrode 21 and the second contact electrode 22 from being damaged due to the influence of the subsequent etching process. The first protection electrode 31 and the second protection electrode 32 may be either a single-layer structure or a multi-layer structure, and their metal materials may include one or more of Cr, Pt, Au, Ni, Ti, and Al.

The first insulating structure 41 covers the plurality of light-emitting structures 12 and the substrate 10, and has a first opening 411 and a second opening 412. The first opening 411 is located on the first contact electrode 21, and the second opening 412 is located on the second contact electrode 22, so that the pads are electrically connected to the contact electrode through the openings in the subsequent process. Further, the first insulating structure 41 includes a first insulating layer and a second insulating layer. The first insulating layer is located between the light-emitting structure 12 and the second insulating layer, the first insulating layer is a SiO₂ film, and the second insulating layer is a DBR reflective layer. Specifically, a SiO₂ film is grown on the light-emitting structure 12 and the substrate 10 first as the first insulating layer by means of plasma enhanced chemical vapor deposition (PECVD), so as to protect the light-emitting layer 16 and a scribe line. Then, a DBR reflective layer composed of two materials, SiO₂ and HfO₂, with different refractive indices and arranged alternately in the manner of ABAB is formed on the first insulating layer as the second insulating layer. In an embodiment, the second insulating layer is composed of three groups of film stacks, and the wavelength bands of the three groups of film stacks are different, which are respectively a UVC wavelength band (wavelength is 200 nm to 280 nm), a UVB wavelength band (wavelength is 280 nm to 315 nm), and a UVA wavelength band (wavelength is 315 nm to 400 nm), so that the reflectivity of the second insulating layer may be higher, such as 99.9%, and ultraviolet light at different light-emitting angles may achieve an ultra-high reflectivity, such as 99.9%.

One end of the bridge electrode 50 is electrically connected to the first contact electrode 21 of the light-emitting structure 12 through the first opening 411, and the other end of the bridge electrode 50 is electrically connected to the second contact electrode 22 of another light-emitting structure 12 through the second opening 412. The bridge electrode 50 is configured to connect the plurality of light-emitting structures 12 in series. Specifically, the bridge electrode 50 is located on the first insulating structure 41 and is covered by the second insulating structure 42.

The second insulating structure 42 covers the first insulating structure 41 and the bridge electrode 50 and has a third opening 423 and a fourth opening 424. Specifically, the second insulating structure 42 is deposited on the first insulating structure 41 and the bridge electrode 50, and the second insulating structure 42 may include SiO₂. Next, the third opening 423 is etched on the light-emitting structure 12 at the head end using an etching process, the fourth opening 424 is etched on the light-emitting structure 12 at the terminal end. The third opening 423 and the fourth opening 424 expose the first contact electrode 21 and the second contact electrode 22, respectively. The head end and the terminal end may be understood as, in the process of electrically connecting the plurality of light-emitting structures 12, the first light-emitting structure 12 is the light-emitting structure 12 at the head end, and the last light-emitting structure 12 is the light-emitting structure 12 at the terminal end.

The first pad 51 and the second pad 52 are arranged on the second insulating structure 42, the first pad 51 is electrically connected to the first contact electrode 21 of the light-emitting structure 12 through the third opening 423, and the second pad 52 is electrically connected to the second contact electrode 22 of the light-emitting structure 12 through the fourth opening 424. The first pad 51 and the second pad 52 may be formed together using the same material in the same process, and thus may have the same layer configuration. However, the present disclosure is not limited thereto, and appropriate materials and layer structures may also be selected for the first pad 51 and the second pad 52 according to actual needs.

In an embodiment, when viewed from the top of the ultraviolet light-emitting device 1 toward the substrate 10, that is, as shown in FIG. 1 and FIG. 2, the second pad 52 is entirely located at the inner side of the first contact electrode 21. In other words, in each light-emitting structure 12, the projection of the second pad 52 on the horizontal plane is entirely located at the inner side of the projection of the first contact electrode 21 on the horizontal plane, that is, the projection of the second pad 52 is not staggered with the projection of the first contact electrode 21. In this manner, it is possible to avoid the risk of short circuit between the second pad 52 and the first contact electrode 21 due to the crack of the first insulating structure 41 and the second insulating structure 42, and also avoid the interdigitated electrode structure, thereby improving the void rate of the surface and enhancing the thrust resistance and reliability of the ultraviolet light-emitting device 1.

There is a first horizontal distance L1 between the first pad 51 and the second pad 52, considering the spacing requirement for the first pad 51 and the second pad 52 in the packaging stage, and avoiding the occurrence of an electrical problem between the first pad 51 and the second pad 52, the range of the first horizontal distance L1 may be 80 μm to 300 μm, preferably 120 μm to 150 μm.

There is a second horizontal distance L2 between the first contact electrode 21 and the second contact electrode 22. In order to avoid the risk of leakage, ESD risk and the like caused by the first contact electrode 21 and the second contact electrode 22 being too close to each other, and to ensure the current spreading capability of the first contact electrode 21 and the second contact electrode 22, the range of the second horizontal distance L2 is 10 μm to 40 μm, preferably 15 μm to 22 μm. In a preferred embodiment, the distance between the first contact electrode 21 and the second contact electrode 22 in the P region is different from the distance between the first contact electrode 21 and the second contact electrode 22 in the N region. The distance between the first contact electrode 21 and the second contact electrode 22 in the P region is greater than the distance between the first contact electrode 21 and the second contact electrode 22 in the N region, for example: the distance between the first contact electrode 21 and the second contact electrode 22 in the light-emitting structure 12 in the P region is 19 μm, and the distance between the first contact electrode 21 and the second contact electrode 22 in the light-emitting structure 12 in the N region is 18 μm, so as to further reduce the void rate of the surface of the first pad 51 and the second pad 52. The light-emitting structure 12 in the P region and the light-emitting structure 12 in the N region may be understood as, the light-emitting structure 12 at the head end is the light-emitting structure 12 in the P region, and the light-emitting structure 12 at the terminal end is the light-emitting structure 12 in the N region.

In an embodiment, as shown in FIG. 1 to FIG. 3, the number of the plurality of light-emitting structures 12 is two, and viewing from the top of the ultraviolet light-emitting device 1 toward the substrate 10, a part of the first contact electrode 21 of one of the light-emitting structures 12 is enclosed by the second semiconductor layer 18 to enhance the luminous performance of the ultraviolet light-emitting device 1. Preferably, the part of the first contact electrode 21 enclosed by the second semiconductor layer 18 is strip-shaped.

The following performance tests are performed on chips with two different structures in FIG. 4A and FIG. 5A, and the two chips have the same size. As shown in FIG. 6, the ultraviolet light-emitting device 1 in FIG. 5A may be driven with a small current (for example, the driving current for the ultraviolet light-emitting device 1 formed by two light-emitting structures 12 connected in series is about half of that for the original single large core particle) by replacing the conventional ultraviolet light-emitting diode having a single large core particle with multiple smaller light-emitting structures 12 connected in series, thereby overcoming the light decay characteristics. Compared with the conventional ultraviolet light-emitting diode shown in FIG. 4A, the external quantum efficiency (EQE) of the ultraviolet light-emitting device 1 shown in FIG. 5A is significantly improved substantially from 2.5% to 5.5%, and the increase rate is as high as 120%, which considerably improves the luminous property of the ultraviolet light-emitting device 1. In addition, compared with the conventional ultraviolet light-emitting diode shown in FIG. 4A, the ultraviolet light-emitting device 1 shown in FIG. 5A also has an increased electro-optical conversion efficiency which is improved from 2.3% to 2.5%, and the increase rate reaches 8.6%. In the aspect of aging, related performance has also been significantly improved, and the perimeter will also be larger, increasing by about 46%, allowing the light-emitting layer to have more opportunities to emit light. That is to say, the loss caused by internal back-and-forth reflection of light emitted by the light-emitting layer due to waveguide effect may be reduced, thus enhancing the luminous property of the ultraviolet light-emitting device 1.

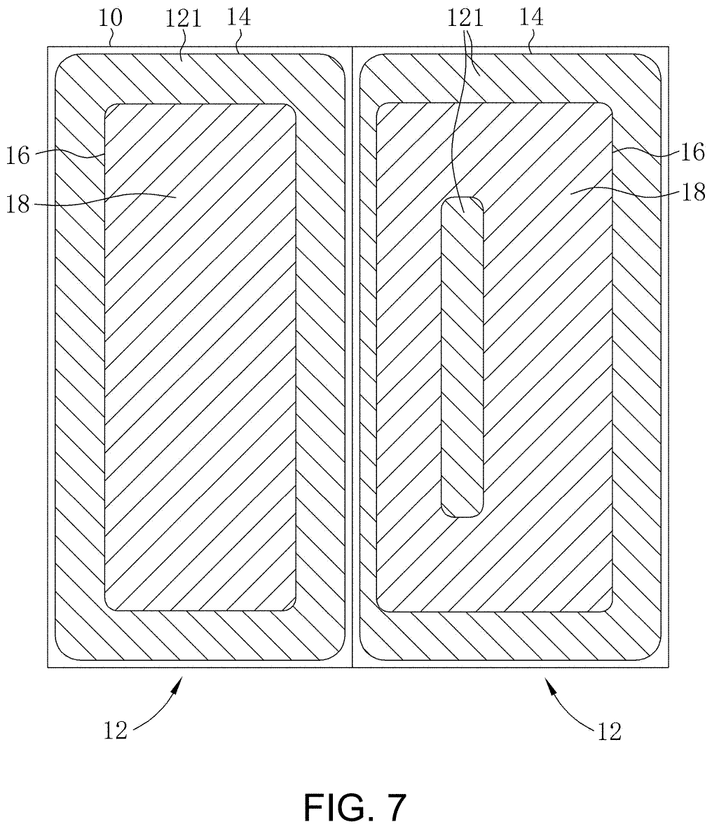

The following discloses a method for manufacturing the ultraviolet light-emitting device 1 shown in FIG. 1. Please refer to FIG. 7 to FIG. 13. FIG. 7 to FIG. 13 are schematic top views showing structures of the ultraviolet light-emitting device 1 shown in FIG. 1 in various stages of a manufacturing process. It should be noted that, the shaded parts in each of the figures in FIG. 7 to FIG. 13 are structures added in the process corresponding to the current figure relative to the process corresponding to the previous figure.

First, referring to FIG. 7, the first semiconductor layer 14, the light-emitting layer 16 and the second semiconductor layer 18 of the light-emitting structure 12 are grown in sequence on the substrate 10. Next, the substrate 10 may be ground and polished to reduce warpage of the substrate 10. Subsequently, the mesa 121 of the light-emitting structure 12 is formed by means of a photomask and a dry etching process to expose the first semiconductor layer 14. Furthermore, an ISA process is performed through a mask and a dry etching process to separate the plurality of light-emitting structures 12 into individual ones. The horizontal projection area of each light-emitting structure 12 corresponds to the sum of the areas of the shaded parts in each light-emitting structure 12 shown in FIG. 7.

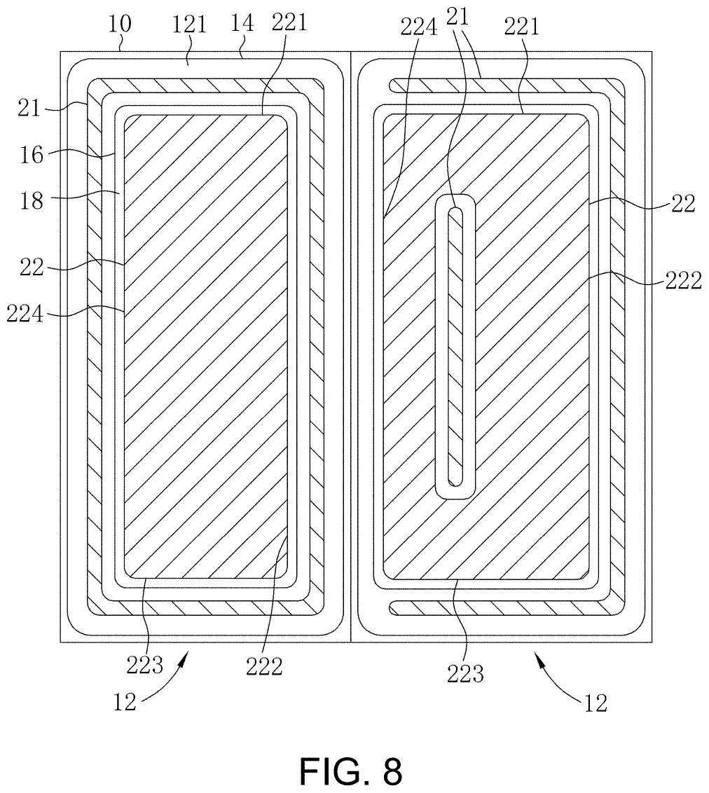

Next, referring to FIG. 8, metal is deposited on the mesa 121 of the first semiconductor layer 14 to form the first contact electrode 21, and the first contact electrode 21 forms an ohmic contact with the first semiconductor layer 14; the second contact electrode 22 is formed on the surface of the second semiconductor layer 18, and the second contact electrode 22 forms an ohmic contact with the second semiconductor layer 18.

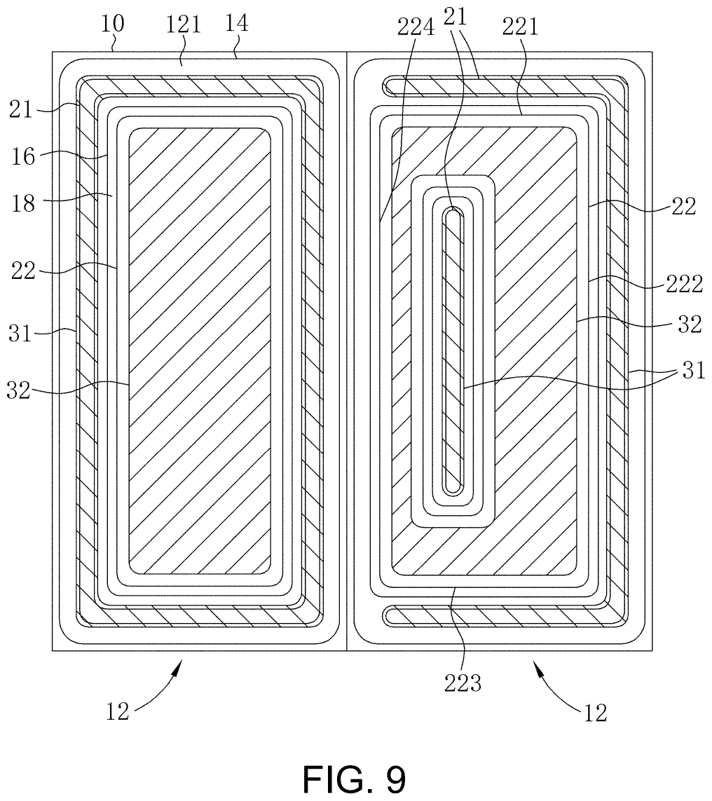

Next, referring to FIG. 9, a first protection electrode 31 and a second protection electrode 32 are grown on the first contact electrode 21 and the second contact electrode 22 respectively, so as to prevent the first contact electrode 21 and the second contact electrode 22 from being damaged in the subsequent manufacturing process.

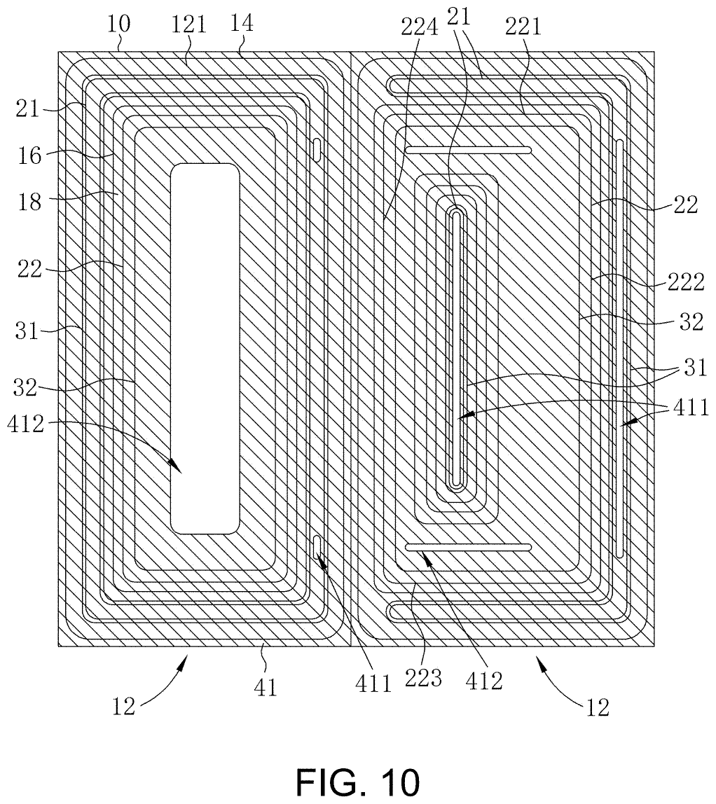

Subsequently, referring to FIG. 10, the first insulating structure 41 is grown on the light-emitting structure 12 and the substrate 10. The first insulating structure 41 covers the substrate 10, the scribe line, the first semiconductor layer 14, the light-emitting layer 16, the second semiconductor layer 18, the first contact electrode 21, the second contact electrode 22, the first protection electrode 31, and the second protection electrode 32. Then, a dry etching process is performed to penetrate the first insulating structure 41 to form through holes, that is, the first opening 411 and the second opening 412, required for connecting die bonding electrodes. The first insulating structure 41 includes a first insulating layer and a second insulating layer. In a specific embodiment, a SiO₂ film may be grown on the light-emitting structure 12 and the substrate first as the first insulating layer by means of plasma enhanced chemical vapor deposition (PECVD), so as to protect the light-emitting layer 16 and the scribe line. Next, a DBR reflective layer composed of two materials, SiO₂ and HfO₂, with different refractive indices and arranged alternately in the manner of ABAB is formed on the first insulating layer as the second insulating layer.

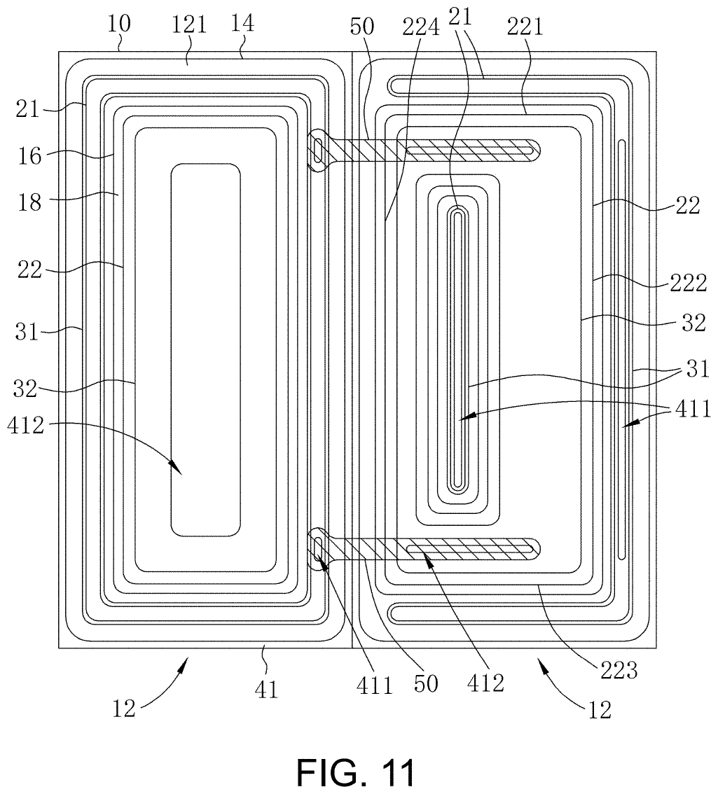

Moreover, referring to FIG. 11, a metal electrode is deposited by vapor deposition as a bridge electrode 50 of the first protection electrode 31 and the second protection electrode 32, and a process for connecting the plurality of light-emitting structures 12 in series is performed. One end of the bridge electrode 50 is electrically connected to the first contact electrode 21 of one light-emitting structure 12 through the first opening 411, and the other end of the bridge electrode 50 is electrically connected to the second contact electrode 22 of another light-emitting structure 12 through the second opening 412.

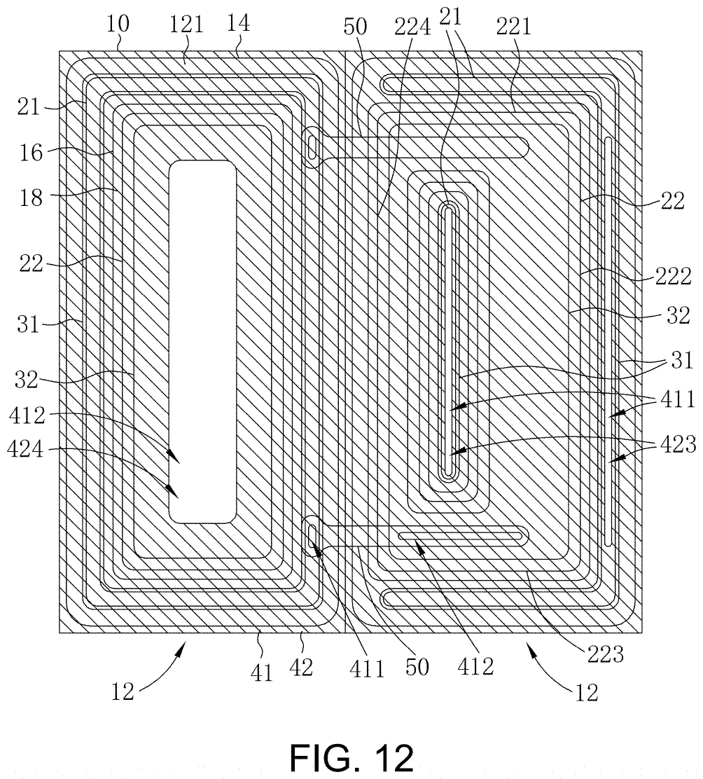

Then, referring to FIG. 12, the second insulating structure 42 is deposited on the first insulating structure 41 and the bridge electrode 50. Almost the entire surface of the second insulating structure 42 covers of the first insulating structure 41 and the bridge electrode 50, but the second insulating structure 42 has the third opening 423 and the fourth opening 424, and the third opening 423 is located on the light-emitting structure 12 at the head end, exposing the first contact electrode 21, and the fourth opening 424 is located on the light-emitting structure 12 at the terminal end, exposing the second contact electrode 22. In an embodiment, the fourth opening 424 and the second opening 412 may be formed together in one etching process, and the third opening 423 and the first opening 411 may also be formed together in one etching process.

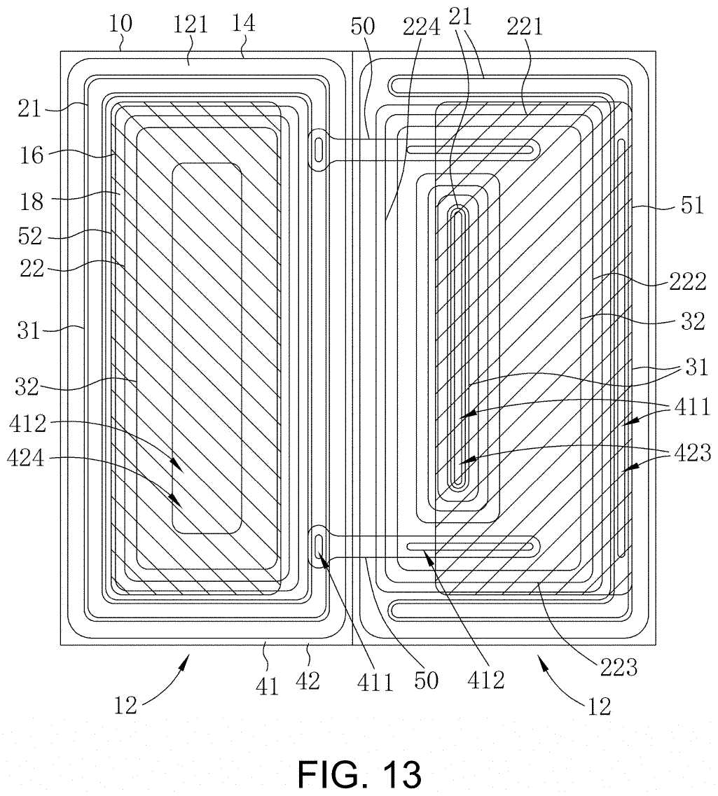

Finally, referring to FIG. 13, the first pad 51 and the second pad 52 are formed on the second insulating structure 42 by a yellow light process and metal evaporation. The first pad 51 is electrically connected to the first contact electrode 21 of the light-emitting structure 12 through the third opening 423, and the second pad 52 is electrically connected to the second contact electrode 22 of the light-emitting structure 12 through the fourth opening 424. Subsequently, a chip may be cut into a specified size using laser cutting and a scribing process. The rear surface of the substrate 10 may also be turned up, and the core particles may be bonded to the heat dissipation substrate by solder paste or AuSn eutectic welding. After the packaging process, a flip-chip ultraviolet light-emitting device 1 package structure may be obtained.

However, the present disclosure is not limited thereto. In other embodiments, the bridge electrode 50 may be formed together with the first protection electrode 31 and the second protection electrode 32 in the same process to save steps and simplify the process. For example: after the first contact electrode 21 and the second contact electrode 22 are arranged, the first insulating structure 41 is grown first, and then the first protection electrode 31, the second protection electrode 32 and the bridge electrode 50 are arranged on the first insulating structure 41. The first protection electrode 31 and the second protection electrode 32 are respectively connected to the first contact electrode 21 and the second contact electrode 22 through the first opening 411 and the second opening 412 of the first insulating structure 41.

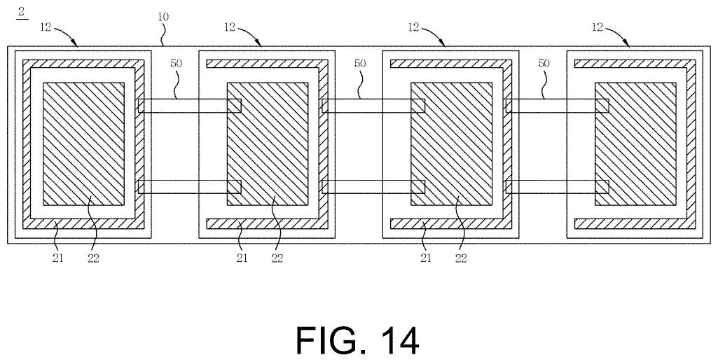

Please refer to FIG. 14. FIG. 14 is a schematic top view showing a structure of a ultraviolet light-emitting device 2 according to another embodiment of the present disclosure. To achieve at least one of the aforementioned advantages or other advantages, another embodiment of the present disclosure further provides a ultraviolet light-emitting device 2. Compared with the ultraviolet light-emitting device 1 shown in FIG. 1, the ultraviolet light-emitting device 2 of the present embodiment is different mainly in that (their similarity will not be repeated here) the number of light-emitting structures 12 is greater than two. When there are a large number of light-emitting structures 12, the plurality of light-emitting structures 12 may be electrically connected in the manner of a strip-shaped distribution as shown in FIG. 14. In particular, in the case of connecting the light-emitting structures 12 in a long strip, a longer perimeter will be obtained as a whole, and no interference will be caused to the extraction of side light, which is more suitable for preparing the ultraviolet light-emitting device 2.

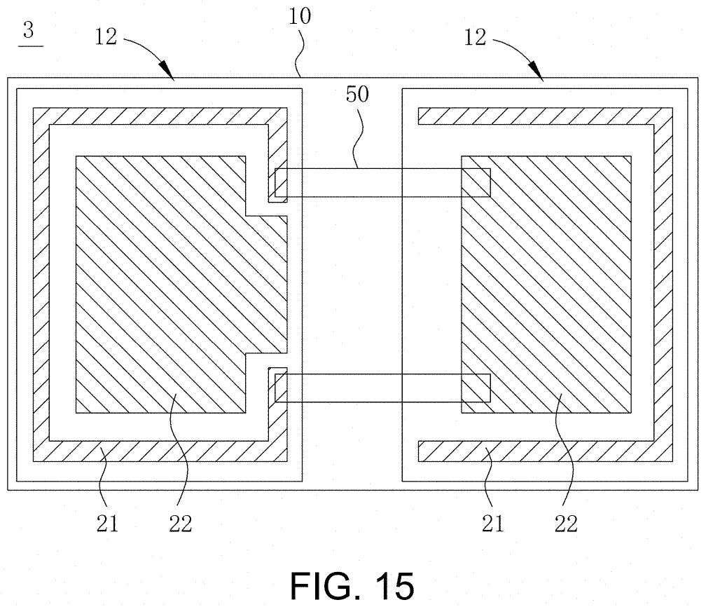

Please refer to FIG. 15. FIG. 15 is a schematic top view showing a structure of a ultraviolet light-emitting device 3 according to still another embodiment of the present disclosure. To achieve at least one of the above advantages or other advantages, another embodiment of the present disclosure further provides a ultraviolet light-emitting device 3. Compared with the ultraviolet light-emitting device 1 shown in FIG. 1, the ultraviolet light-emitting device 3 of the present embodiment is different mainly in that (their similarity will not be repeated here) the second contact electrode 22 in the left light-emitting structure 12 is in a “convex” shape, and the first contact electrode 21 no longer completely encloses the four edges of the second contact electrode 22, so that more light-emitting layers 16 may be retained, and the luminous property of the ultraviolet light-emitting device 3 may be improved. In addition, the ultraviolet light-emitting device 1 shown in FIG. 1 may be provided with more bridge electrodes 50 to form more paths in series connection, so as to ensure the stability of the circuit connected in series. Preferably, the first contact electrode 21 is an N-type electrode, and the second contact electrode 22 is a P-type electrode.

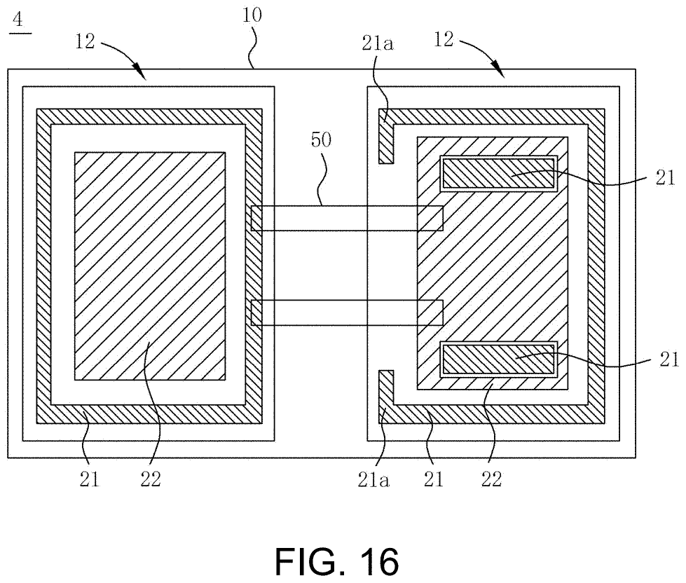

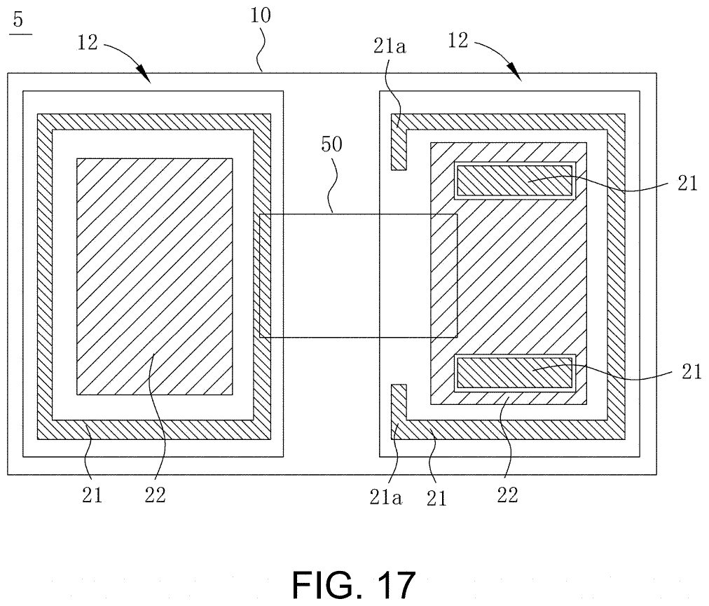

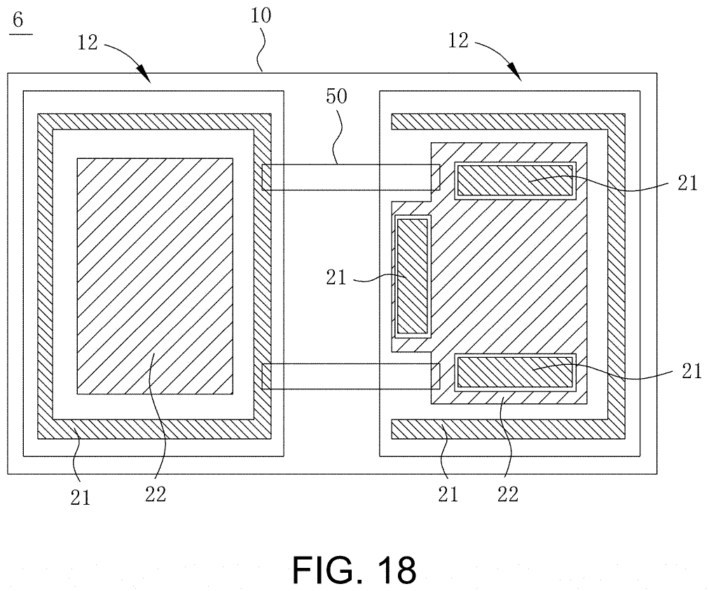

Please refer to FIG. 16 to FIG. 18. The light-emitting structure 12 on the left side of the ultraviolet light-emitting devices 4, 5, and 6 in FIG. 16 to FIG. 18 serves as a P pad region (the region where the second pad is set), and the light-emitting structure 12 on the right serves as the N pad region (the region where the first pad is set). The first contact electrode 21 is an N-type electrode, and the second contact electrode 22 is a P-type electrode. Maintaining a small void rate in the pad region (P pad region and N pad region) helps to improve the thrust of the electrode and thus improving reliability. Therefore, the N-type electrode will be set to be close to the edge of the light-emitting structure 12 as much as possible to maintain the maximization of the opening (the openings of the second insulating structure 42) in the pad region, thereby keeping the void rate low. The bridge electrodes 50 are mainly composed of two bridge circuits and a ribbon-shaped circuit (or change to three bridge circuits to approximate a ribbon-shaped circuit) bridge electrode 50. The connection between the N-type contact electrode of the left light-emitting structure 12 and the P-type contact electrode of the right light-emitting structure 12 is formed mainly through the bridge electrode 50. In FIG. 16 and FIG. 17, the N-type electrodes in the N pad region are also mainly around the edge of the light-emitting structure 12, and two corner electrodes 21a are additionally provided near the bridge electrode 50 to increase the N-type electrode area in the N pad region; such configuration helps reduce the rise of forward voltage after cascading. The N-type electrode located inside the P-type electrode is also set close to the edge of the light-emitting structure 12 as much as possible to maintain the flat region in the center and achieve a low void rate. In FIG. 18, because the bridge electrodes 50 of the N pad region on the left and right sides are set toward the outside, the N-type electrodes located inside the P-type electrode are mainly designed as three small pieces of N-type electrodes, and the first and second holes are opened, while the P-type electrodes are mainly designed as three small pieces of N-type electrodes in a convex shape, thereby increasing the area of the P-type electrode in the N pad region, and improving thrust resistance and stability.

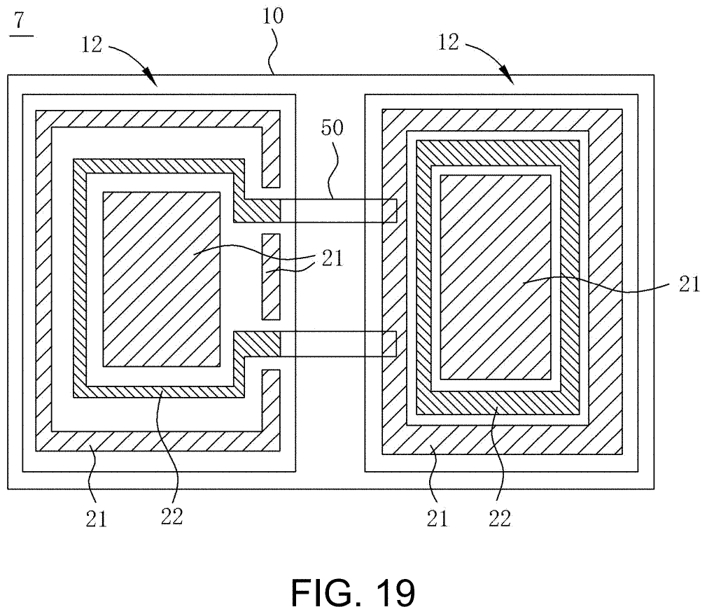

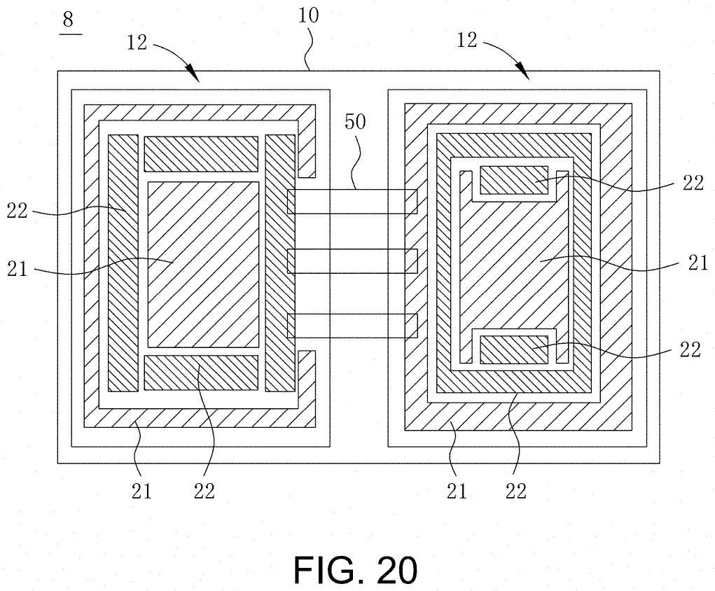

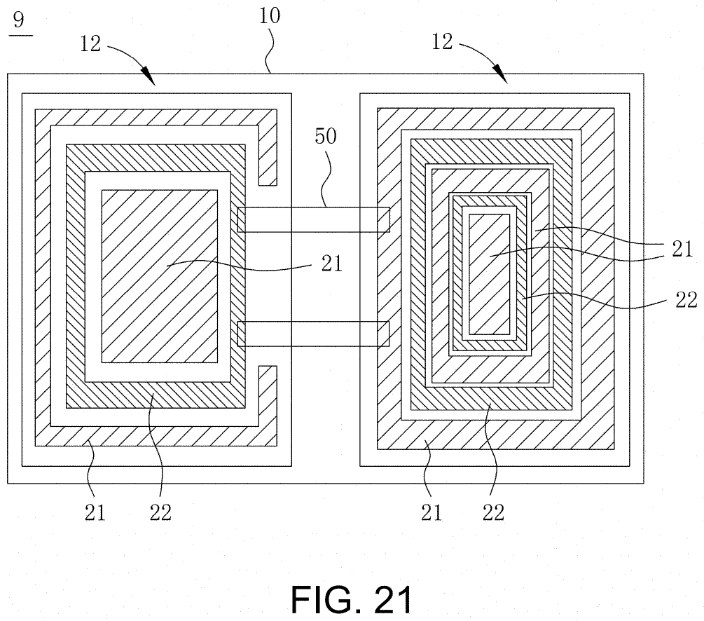

Please refer to FIG. 19 to FIG. 21. The light-emitting structure 12 on the left side of the ultraviolet light-emitting devices 7, 8, and 9 in FIG. 19 to FIG. 21 serves as a P pad region (the region where the first pad is set), and the light-emitting structure 12 on the right serves as the N pad region (the region where the second pad is set). The first contact electrode 21 is a P-type electrode, and the second contact electrode 22 is an N-type electrode. Maintaining a small void rate in the pad region (P pad region and N pad region) helps to improve the thrust of the electrode and thus improving reliability. Therefore, the N-type electrode may be made into a shape similar to “ [symbol] ” as much as possible to set the opening (the opening of the second insulating structure 42) of the pad region at the edge of the light-emitting structure 12 as close as possible to maintain the flatness of the P-type electrode in the center. The bridge electrodes 50 are mainly composed of two bridges and three bridges. The connection between the N-type contact electrode of the left light-emitting structure 12 and the P-type contact electrode of the right light-emitting structure 12 is formed mainly through the bridge electrode 50. In the N pad region, in consideration of the design in which the P-type electrode encloses the N-type electrode, to protect the current injection performance of the N-type electrode, as shown in FIG. 20, two small pieces of N-type electrodes are arranged in the middle region, and the N-type electrodes in the middle region are set to be located on both sides toward the outer side, so that the central region is kept as flat as possible to maintain a low level of void rate. However, this setting method results in a relatively high void rate. To solve this problem, as shown in FIG. 19, the two small pieces of N-type electrodes in the middle region in FIG. 20 may be removed, and a P-type electrode may be formed on the entire surface in the middle to maintain a lower level of void rate. In addition, in FIG. 21, the N-type electrode is formed into a shape of “ [symbol] ” so as to further reduce the void rate, maintain the thrust, and improve reliability.

It should be further explained that the various figures may be adaptively combined to form a ultraviolet light-emitting device with a new morphology. For example: the left light-emitting structure 12 of FIG. 16 and the right light-emitting structure 12 of FIG. 20 may be combined adaptively, or the left light-emitting structure 12 of FIG. 16 and the right light-emitting structure 12 of FIG. 21 may be combined adaptively and so on, and the above combinations have their own characteristics. Moreover, when the second contact electrode 22 does not only have four edges, the configuration in which the first contact electrode 21 at least encloses three edges of the second contact electrode 22 may be understood as at least enclosing more than 75% of the outer circumference of the second contact electrode 22.

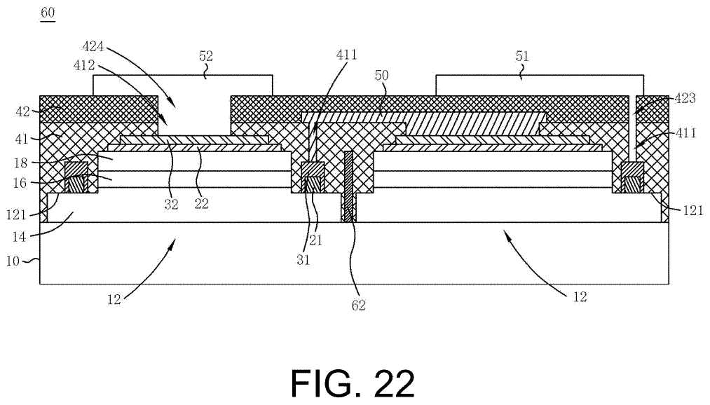

Please refer to FIG. 22. FIG. 22 is a schematic view showing a structure of an ultraviolet light-emitting device 60 according to another embodiment of the present disclosure. To achieve at least one of the above advantages or other advantages, another embodiment of the present disclosure further provides an ultraviolet light-emitting device 60. Compared with the ultraviolet light-emitting device 1 shown in FIG. 1, the ultraviolet light-emitting device 60 of the present embodiment is different mainly in that (their similarity will not be repeated here) the ultraviolet light-emitting device 60 further includes a high-reflection layer 62, and the high-reflection layer 62 is arranged between the channels of two adjacent light-emitting structures 12 to reflect the light emitted by the light-emitting layer 16, thereby improving the light output performance of the ultraviolet light-emitting device 60. The high-reflection layer 62 may be a metal reflection structure, a DBR reflective structure, an ODR reflection structure, or the like.

An embodiment of the present disclosure provides a light-emitting device, which adopts the ultraviolet light-emitting devices 1, 2, and 3 as described in any of the foregoing embodiments. The light-emitting device has good optoelectronic properties.

In conclusion, compared with the related art, the ultraviolet light-emitting devices 1, 2, 3 and the light-emitting device provided by the present disclosure have good optoelectronic properties.

What is claimed is:

1. An ultraviolet light-emitting device, comprising:
a substrate;
a plurality of light-emitting structures, disposed on the substrate, wherein the plurality of light-emitting structures are electrically connected to each other, each of the plurality of light-emitting structure comprises a first semiconductor layer, a light-emitting layer, a second semiconductor layer, a first contact electrode, and a second contact electrode, the light-emitting layer is located between the first semiconductor layer and the second semiconductor layer, the first contact electrode is located on the first semiconductor layer, and the second contact electrode is located on the second semiconductor layer;
wherein viewing from the top of the ultraviolet light-emitting device toward the substrate, the second contact electrode of each of the plurality of light-emitting structures has four edges, and the four edges are sequentially defined as a first edge, a second edge, a third edge, and a fourth edge in an annular direction, and the first contact electrode at least surrounds three edges of the four edges.

2. The ultraviolet light-emitting device according to claim 1, wherein each of the plurality of light-emitting structures has a mesa, the mesa refers to an upper surface of the first semiconductor layer that is not shielded by the light-emitting layer, a horizontal projection area of the mesa of each of the plurality of light-emitting structures accounts for 30%-70% of a horizontal projection area of each of the plurality of light-emitting structures.

3. The ultraviolet light-emitting device according to claim 1, wherein each of the plurality of light-emitting structures further comprises a first protection electrode which covers the first contact electrode.

4. The ultraviolet light-emitting device according to claim 1, wherein the ultraviolet light-emitting device further comprises a first insulating structure, the first insulating structure covers the plurality of light-emitting structures, and has a first opening and a second opening.

5. The ultraviolet light-emitting device according to claim 4, wherein the first insulating structure comprises a first insulating layer and a second insulating layer, the first insulating layer is located between the light-emitting structure and the second insulating layer, the first insulating layer is a SiO₂ film, and the second insulating layer is a DBR reflective layer.

6. The ultraviolet light-emitting device according to claim 4, wherein the ultraviolet light-emitting device further comprises a bridge electrode, one end of the bridge electrode is electrically connected to the first contact electrode of the light-emitting structure through the first opening, and the other end of the bridge electrode is electrically connected to the second contact electrode of another light-emitting structure through the second opening.

7. The ultraviolet light-emitting device according to claim 6, wherein the ultraviolet light-emitting device further comprises a second insulating structure, a first pad and a second pad, the second insulating structure covers the first insulating structure and the bridge electrode, and has a third opening and a fourth opening, the first pad is electrically connected to the first contact electrode of the light-emitting structure through the third opening, and the second pad is electrically connected to the second contact electrode of the light-emitting structure through the fourth opening.

8. The ultraviolet light-emitting device according to claim 7, wherein viewing from the top of the ultraviolet light-emitting device toward the substrate, the second pad is entirely located at an inner side of the first contact electrode.

9. The ultraviolet light-emitting device according to claim 7, wherein viewing from the top of the ultraviolet light-emitting device toward the substrate, the projection of the second pad does not overlap the projection of the first contact electrode.

10. The ultraviolet light-emitting device according to claim 7, wherein there is a first horizontal distance between the first pad and the second pad, and a range of the first horizontal distance is 80 μm to 300 μm.

11. The ultraviolet light-emitting device according to claim 1, wherein there is a second horizontal distance between the first contact electrode and the second contact electrode, and a range of the second horizontal distance is 10 μm to 40 μm.

12. The ultraviolet light-emitting device according to claim 1, wherein a horizontal projection area of the first contact electrode accounts for 10% to 40% of a horizontal projection area of the light-emitting structure.

13. The ultraviolet light-emitting device according to claim 1, wherein the plurality of light-emitting structures are connected in series.

14. The ultraviolet light-emitting device according to claim 1, wherein the number of the plurality of light-emitting structures is two, and viewing from the top of the ultraviolet light-emitting device toward the substrate, a part of the first contact electrode of one of the light-emitting structures is enclosed by the second semiconductor layer.

15. The ultraviolet light-emitting device according to claim 1, wherein a part of the first contact electrode of one of the light-emitting structures is enclosed by the second semiconductor layer.

16. The ultraviolet light-emitting device according to claim 15, wherein the part of the first contact electrode enclosed by the second semiconductor layer is strip-shaped.

17. The ultraviolet light-emitting device according to claim 15, wherein the first semiconductor layer is an n-type AlGaN layer, the second semiconductor layer is a p-type AlGaN layer or a p-type GaN layer, or a stacked structure in which a p-type AlGaN layer and a p-type GaN layer are stacked.

18. The ultraviolet light-emitting device according to claim 1, wherein the first contact electrode is set to be close to the edge of the light-emitting structure.

19. The ultraviolet light-emitting device according to claim 7, wherein the second pad is arranged over a first light-emitting structure which maintains a flat region in the center.

20. A light-emitting apparatus, adopting the ultraviolet light-emitting device as claimed in claim 1.
